(19) United States
(12) Patent Application Publication
(10) Pub. No.: US 2026/0173550 A1
(43) Pub. Date: Jun. 18, 2026

(54) DEPTH IMAGE SENSOR HAVING A CHARGE-DOMAIN ARCHITECTURE

(71) Applicant: COMMISSARIAT A L' ENERGIE ATOMIQUE ET AUX ENERGIES ALTERNATIVES, PARIS (FR)

(72) Inventors: Gaëlle PALMIGIANI, GRENOBLE CEDEX 09 (FR); Olivier SAXOD, GRENOBLE CEDEX 09 (FR)

(73) Assignee: COMMISSARIAT A L' ENERGIE ATOMIQUE ET AUX ENERGIES ALTERNATIVES, PARIS (FR)

(21) Appl. No.: 19/418,260

(22) Filed: Dec. 12, 2025

(30) Foreign Application Priority Data
Dec. 13, 2024 (FR) FR2414062

(51) Int. Cl. H10F 39/15; H10F 39/00

(52) U.S. Cl. CPC H10F 39/151; H10F 39/80373

(57) ABSTRACT

The invention relates to an image sensor comprising at least one depth pixel comprising two controllable storage zones. Each comprises a memory region separated from a photosensitive region by an electric potential barrier; a transfer gate extending opposite the barrier; a reverse transfer gate extending opposite the barrier and an upper part of the photosensitive region. A charge flow path extending between the transfer gates, vertically in line with the photosensitive region, comprises a collection zone separated from the photosensitive region by a channel. A circuit is configured to: sample a signal in each memory; and for each storage zone, empty the memory by activating the transfer gates and the reverse transfer gate of the storage zone between one reset and one reading of a sense node.

### TECHNICAL FIELD

The field of the invention is that of depth image sensors operating on an indirect time-of-flight measurement principle.

### STATE OF PRIOR ART

Depth image sensors allow to obtain an image in relief of a scene. Such sensors include depth image sensors based on an indirect time-of-flight measurement principle, generally referred to as iToF (Indirect Time of Flight) image sensors. Such a depth image sensor generally comprises an array of depth pixels. It is associated with a light source, for example a laser, for illuminating the scene. The light source emits a light signal that is periodic in amplitude, often sinusoidal. A pixel, or a group of contiguous pixels corresponding to a point of the image, samples the periodic signal received after reflection on the scene. The sensor comprises processing means for determining a phase shift between the periodic signals emitted and received, and converting the phase shift into a distance separating the image sensor from the point of the scene combined with the point of the image.

It is commonly accepted that at least three samples over a period of the periodic signal are required to perform a distance measurement. It is preferable to use at least four samples. A sample is an integration of the periodic signal received by a pixel for one or more time periods, each equal to a fraction of the period of the periodic signal, the time periods being spaced apart by a period of the periodic signal. Preferably, the fraction of the period of the periodic signal is the same for all the samples, for example equal to the reciprocal of the number of samples. Generally, the integration time periods of separate samples do not overlap.

A depth pixel typically comprises a photosensitive region configured to convert the photons of the light signal received into electric charges, as well as a transfer transistor and a sense node per sampling branch or for several sampling branches. The transfer transistor allows to transfer the electric charges from the photosensitive region to the sense node during the time periods corresponding to a sample.

Among the depth pixels operating on a principle of measuring indirect time-of-flight, there are two different families, namely charge-domain architectures and voltage-domain architectures.

In a depth pixel according to a voltage-domain architecture, the sense node is directly connected to a source or a drain of the transfer transistor. The transfer transistor switches to the on state during the integration time periods of a sample. Thus, photogenerated charges accumulate on the sense node during a sampling phase, varying a sampling potential of the sense node. The sampling potential is then read at the end of the sampling phase. The sense node must be reset between each sampling. It can be reset to a reset potential at the beginning of the sampling phase and/or after the reading of the sampling potential. The reading of the sampling potential is compared to a reading of the reset potential on the sense node to determine the value of the sample. However, the resetting of the sense node adds thermal noise to the reset potential, commonly called kTC noise, which affects the value of the sample in this type of architecture.

A charge-domain architecture allows to implement a technique for reducing the kTC noise known as Correlated Double Sampling (CDS). A depth pixel according to a charge-domain architecture comprises a memory and a second transfer transistor for each sampling branch, arranged between the transfer transistor and the sense node. The memory is consequently decoupled from the sense node by the channel of the second transfer transistor. An example of a depth pixel having a charge-domain architecture is given in document US 2019/0086519.

The photogenerated charges accumulate in the memory during the integration time periods of a sample. At the end of the sampling phase, the sense node is reset to a reset potential which is read before a transfer of the electric charges stored in the memory to the sense node by activation of the second transfer transistor. A reading of the potential of the sense node after transfer is subtracted from the read value of the reset potential to obtain the value of the sample. Since the two readings occur immediately one after the other, without switching of a switch, the kTC noises are correlated and are therefore eliminated during the subtraction.

For a charge-domain architecture, the memory is however cumbersome and often occupies a blind region of the depth pixel. However, it is not desirable to reduce its footprint at the risk of compromising a dynamic range of the samples, that is to say the maximum difference between two sample values that the depth pixel or the image sensor can record simultaneously. This constraint is all the more exacerbated when the size of the depth pixel is reduced to increase a resolution of the sensor, or when the photosensitive region is large to increase its sensitivity.

Specific image sensors exist, often called RGBZ sensors, allowing to obtain an intensity image of a scene containing information on distance between the sensor and the scene. Such sensors generally comprise a plurality of blocks of pixels, each block of pixels comprising an image group of at least one intensity pixel and a macro-pixel Z comprising at least one depth pixel. The image group is configured to give information on intensity of an observed scene. The macro-pixel Z is configured to give information on distance separating the scene from the sensor. In an RGBZ sensor, the image group generally consists of three intensity pixels, one sensitive pixel in red, one in green and one in blue. All the pixels are arranged into an array. It is consequently preferable that the depth pixels have substantially the same size as the intensity pixels. It is therefore desirable that the size of the depth pixels follow the same reduction trend as the intensity pixels. This often makes it difficult or even impossible to adopt a charge-domain architecture.

There is therefore a need for a more compact depth pixel and/or a new depth pixel architecture allowing correlated double sampling, without compromising on the size of the depth pixel, the resolution or the sensitivity of the image sensor.

### DISCLOSURE OF THE INVENTION

The purpose of the invention is to at least partially overcome drawbacks of prior art, and more particularly to provide an image sensor comprising a plurality of pixels, at least one of which is a depth pixel for collecting several samples, being more compact than the depth pixels of prior art.

For this, the object of the invention is an image sensor comprising a readout circuit and a plurality of pixels formed in and/or on a substrate of the sensor, such that at least one of the pixels is a depth pixel, each depth pixel comprising a photosensitive region of the substrate, a first and a second controllable storage zones.

Each controllable storage zone comprises: an electric charge flow path extending vertically in the substrate vertically in line with the photosensitive region and comprising a memory region which is a potential well and a barrier which is an electric potential barrier interposed between the memory region and the photosensitive region; a transfer gate extending vertically in the substrate vertically in line with the photosensitive region, opposite the barrier; a reverse transfer gate extending vertically in the substrate opposite the barrier and opposite an upper part of the photosensitive region.

Each depth pixel comprises an additional electric charge flow path extending vertically in the substrate between the respective transfer gates of the first and second controllable storage zones, vertically in line with the photosensitive region, comprising a collection zone which is an electric potential well and a collection channel which is an electric potential barrier interposed between the collection zone and the photosensitive region.

The readout circuit comprises a sense node electrically connected to the collection zone and is configured to successively: apply, in each controllable storage zone, a periodic pulse train to the transfer gate during a sampling phase common to the first and second controllable storage zones, so as to make electric charges flow from the photosensitive region to the memory region during the pulses, the respective pulse train of the first and second controllable storage zones being phase shifted relative to each other, and with the same period; perform a first reset of the sense node; perform a first charge evacuation during which the transfer gates of the first and second controllable storage zones, and the reverse transfer gate of the first controllable storage zone are activated so as to make the electric charges flow from the memory region of the first controllable storage zone to the collection zone; read an electric potential Vsig1 of the sense node; perform a second reset of the sense node; perform a second charge evacuation during which the transfer gates of the first and second controllable storage zones, and the reverse transfer gate of the second controllable storage zone are activated so as to make the electric charges flow from the memory region of the second controllable storage zone to the collection zone; read an electric potential Vsig2 of the sense node.

Some preferred, but not limited to, aspects of this sensor are as follows.

The readout circuit can be configured to read an electric potential Vinit1 of the sense node between the first reset and the first evacuation, and an electric potential Vinit2 of the sense node between the second reset and the second evacuation. The sensor may be configured to perform a first correlated double sampling from Vinit1 and Vsig1, and a second correlated double sampling from Vinit2 and Vsig2.

Each controllable storage zone may comprise a pinning gate. In each controllable storage zone, the flow path may comprise a pinning zone capable of covering the memory region on a side of the memory region opposite the barrier, the pinning gate may extend vertically in the substrate facing the memory region, and the readout circuit can be configured to apply an electric potential difference between the pinning zone and the pinning gate so as to passivate the memory region from electric charges coming from the pinning zone.

In each controllable storage zone, the pinning gate may be housed in a notch made in the reverse transfer gate.

The collection zone can extend vertically in the substrate deeper than the memory regions of the first and second controllable storage zones.

For each depth pixel, the collection channel, the collection zone, the barrier, and the memory region of each controllable storage zone may be doped with a first type of conductivity, and each memory region may have a dopant concentration strictly lower than a dopant concentration of the collection zone.

For each depth pixel, each pinning zone may be doped with a second type of conductivity opposite to the first type of conductivity.

The collection channel and the barrier of each controllable storage zone may have identical dopant concentrations.

For each depth pixel, the transfer gate of each controllable storage zone may have the shape of a U in a top view, which may surround the flow path.

The readout circuit may comprise one reset electric contact per depth pixel. Each depth pixel may comprise a peripheral contact zone of the first type of conductivity as one-piece with the collection zone, arranged at the periphery of the depth pixel, on which the reset electric contact rests.

For each depth pixel and each controllable storage zone, the pinning gate may occupy a notch made in the reverse transfer gate.

The plurality of pixels may be arranged in an array and wherein the pinning gates and the reverse transfer gates may be arranged in separation planes between two pixels of the array of pixels.

All the pixels in the array can have the same size. The array of pixels can comprise intensity pixels configured to deliver a signal representative of an intensity of an incident light radiation.

### BRIEF DESCRIPTION OF THE DRAWINGS

Other aspects, aims, advantages and characteristics of the invention will become apparent upon reading the following detailed description of preferred embodiments thereof, provided as a non-limiting example, and made with reference to the appended drawings wherein:

FIG. 1B is a schematic view along the cross-section A-A of FIG. 1A of the example of a depth pixel;

FIG. 2A is an electrical schematic of a readout circuit adapted to the depth pixel of FIGS. 1A and 1B;

FIG. 2B is a timing diagram illustrating a possible operation of the readout circuit;

FIG. 3 is a schematic top view of an alternative of the depth pixel of FIGS. 1A and 1B;

FIG. 4 is a partial schematic top view of an array of depth pixels;

FIG. 5 is a partial schematic top view of an array of pixels mixing intensity pixels and depth pixels;

FIG. 6 is a schematic view along the cross-section A-A of FIG. 4 or FIG. 5.

### DETAILED DISCLOSURE OF SPECIFIC EMBODIMENTS

In the figures and in the following description, the same references represent identical or similar elements. Furthermore, the different elements are not represented to scale so as to improve the clarity of the figures. Moreover, the different embodiments and alternatives are not mutually exclusive and could be combined together. Unless stated otherwise, the terms “substantially”, “about”, and “in the range of” mean within a 10% margin, and preferably within a 5% margin. Moreover, the terms “between . . . and . . . ” and equivalents mean that the bounds are included, unless specified otherwise.

The invention concerns an image sensor. The sensor comprises a substrate, a readout circuit and a plurality of pixels formed in and/or on the substrate. At least one out of the plurality of pixels is a depth pixel.

Each depth pixel comprises a photosensitive region. It further comprises a first and a second controllable storage zones arranged vertically in line with the photosensitive region. Each controllable storage zone comprises an electric charge flow path, a transfer gate, a reverse transfer gate, and an optional pinning gate. The flow path comprises a memory region separated from the photosensitive region by a barrier.

Each depth pixel further comprises an additional electric charge flow path, also arranged vertically in line with the photosensitive region, comprising a collection zone separated from the photosensitive region by an electric potential barrier called collection channel. A sense node of the readout circuit is electrically connected to the collection zone.

For each controllable storage zone, the gates extend vertically in the substrate. The transfer gate is vertically in line with the photosensitive region. The transfer gate and the reverse transfer gate extend opposite the barrier, so that the latter can be controlled indifferently by the transfer gate or by the reverse transfer gate, or by both simultaneously. Furthermore, the reverse transfer gate extends opposite an upper part of the photosensitive region, so as to be able to change the sign of a difference in electric potentials between the memory region and the photosensitive region.

This arrangement in combination with a particular configuration of the readout circuit makes it possible to control each storage zone so as to allow a two-way flow of the electric charges in the flow path. It is thus possible to accumulate photogenerated electric charges in the memory region during a sampling phase and to evacuate them during a reading phase to the collection zone. An electric potential of the sense node is then read by the readout circuit. It corresponds to the number of charges accumulated, then transferred. The memory region thus emptied can be used as a receptacle for a new sampling phase.

During operation, the photosensitive region is intended to receive incident electromagnetic radiation on a lower face of the substrate opposite to the controllable storage zone. Thus, the depth pixel is compact and has no or few blind regions.

The additional electric charge flow path extends vertically between the transfer gates. The transfer gates are arranged so as to be able to control the collection channel. Simultaneous activation of the transfer gates makes the transfer of electric charges from the photosensitive region to the collection zone preferential, compared to a transfer to a memory region of a controllable storage zone. Thus, it is possible to reset the photosensitive region or, optionally, to evacuate photogenerated charges not to be collected during the sampling phase, without additional gates and/or interconnections. This increases the depth pixel compactness.

In the description, a transfer of electric charges from a first region along a channel, or to a second region, is said to be preferential, if at least 90% of the electric charges transferred from the first region are transferred by this channel, or reach the second region. Where applicable, the proportion is preferably greater than or equal to 95%, or greater than or equal to 97%, or even greater than or equal to 99%.

Particular embodiments relating to an image sensor comprising a NMOS transistor-based readout circuit will be described. However, these embodiments can be adapted to other types of readout circuits allowing to implement the technical teaching of the description without departing from the scope of the invention. For example, it is possible to use a readout circuit based on PMOS transistors or a combination of NMOS and PMOS transistors.

Similarly, each embodiment described hereinafter adopts a particular combination of conductivities associated with the doped zones, it being understood that the combination can be inverted without departing from the scope of the invention. Thus, for a particular embodiment, all P-doped zones can be N-doped and all N-doped zones can be P-doped, provided that the type of conductivity of all of the doped zones is changed. The examples of electric potentials or bias voltages given in the description are given relative to the specific combination of conductivities and doping concentrations taken for the exemplary embodiments, in association with an example of an NMOS readout circuit. A person skilled in the art is capable of establishing the electric potentials and/or the bias voltages suitable for other possible combinations within the scope of the invention.

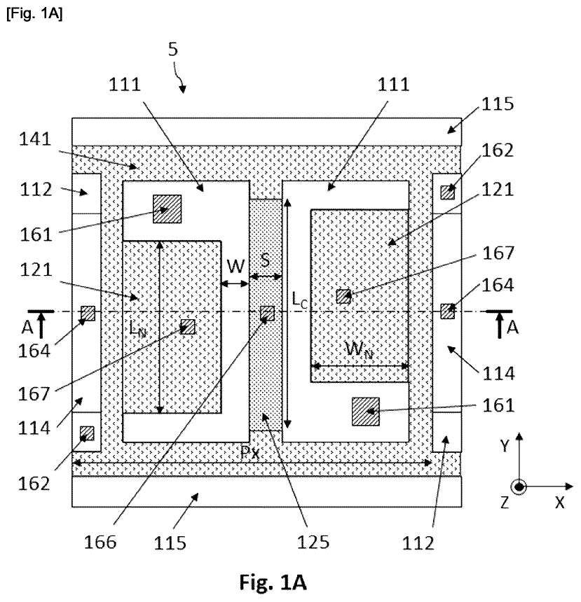

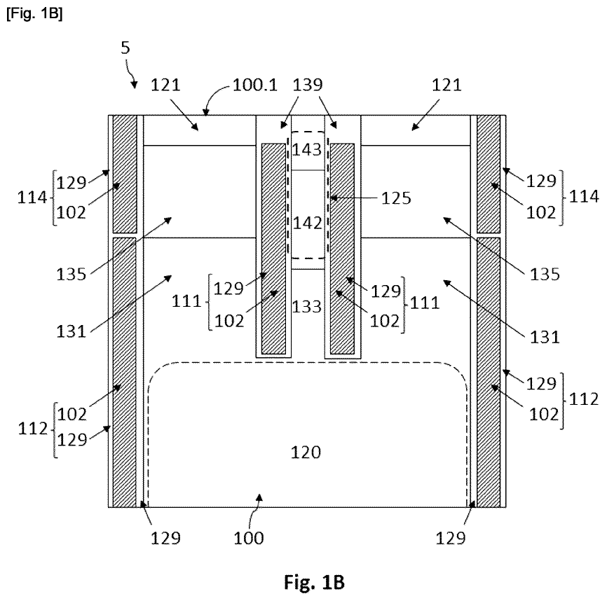

An example of a depth pixel 5 of an image sensor according to the invention will now be described in relation to FIGS. 1A and 1B. FIGS. 1A and 1B are schematic top and cross-section views, respectively. The sectional plane of FIG. 1B is represented by a dash-dotted line in FIG. 1A.

The image sensor comprises a readout circuit and a plurality of pixels formed in and on a substrate 100, at least one of which is a depth pixel 5. In FIGS. 1A to 1B, only one depth pixel 5 has been represented. In order not to overload the diagrams, some elements have been omitted, such as interconnection lines or some electric contacts, for example. To improve readability, only an upper part of the substrate 100 is represented in the cross-section view. In the schematic views, the elements are represented by simple geometric shapes. These are reproduced on the device produced excluding manufacturing errors, such as alignment, dimensional errors or corner roundings caused by a lack of resolution.

The substrate 100 comprises an upper face 100.1 and a lower face opposite the upper face 100.1. The lower and upper faces 100.1 are substantially planar and parallel to each other. The depth pixel 5 comprises a photosensitive region 120, a first and a second controllable storage zones. Each controllable storage zone comprises a flow path. The flow path comprises a barrier 131, a memory region 135 and a pinning zone 121.

The controllable storage zones are preferably similar or identical. They can for example be obtained, one from another, by an isometry of the space, such as for example an orthogonal symmetry with respect to a plane, or with respect to an axis. In this example, the second controllable storage zone is deduced from the first controllable storage zone by axial symmetry with respect to an axis perpendicular to the upper face 100.1, passing through the center of the depth pixel 5. Thus, only the first controllable storage zone is explicitly described hereinafter.

The depth pixel 5 comprises an additional flow path. The additional flow path comprises a collection zone 125 and a collection channel 133. In this example, the pinning zone 121 of each controllable storage zone and the collection zone 125 are flush with the upper face 100.1. The flow path of each controllable storage zone and the additional flow path extend vertically in the substrate 100 vertically in line with the photosensitive region 120, between the photosensitive region 120 and the upper face 100.1 of the substrate 100.

Herein and for the remainder of the description, an orthogonal three-dimensional direct reference frame (X, Y, Z) is defined, wherein the axes X and Y form a plane parallel to the upper face 100.1 of the substrate 100, the axis X being oriented parallel to the sectional plane A-A of FIG. 1A, and wherein the axis Z is oriented substantially orthogonally to the upper face 100.1, from the photosensitive region 120 to the upper face 100.1. In the following description, the terms “vertical” and “vertically” are defined as relating to an orientation substantially parallel to the axis Z, and the terms “horizontal” and “horizontally” as relating to an orientation substantially parallel to the plane (X, Y). Furthermore, the terms “lower” and “upper” are defined as relating to an increasing position when moving away from the upper face 100.1 of the substrate 100 in the +Z direction. The term “lateral” refers to an orientation substantially parallel to the axis Z.

The substrate 100 is made of a semiconductor material. Here it is made of crystalline silicon. For example, it consists of a silicon wafer or part of a silicon wafer. It can comprise one or more epitaxially grown layers of crystalline silicon, as well as one or more passivation layers.

The barrier 131 is arranged between the photosensitive region 120 and the memory region 135. The barrier 131 constitutes an electric potential barrier for electric charges intended to be photogenerated in the photosensitive region 120. The photogenerated electric charges here are electrons of a conduction band of the photosensitive region 120. The memory region 135 constitutes an electric potential well for the photogenerated electric charges.

The pinning zone 121 covers the memory region 135, on a side of the memory region 135 opposite to the barrier 131. The pinning zone 121 preferably completely covers the memory region 135. The controllable storage zone further comprises a pinning gate 114. The pinning gate 114 extends vertically in the substrate 100 opposite the memory region 135. The pinning zone 121 and/or the pinning gate 114 are intended to set a so-called pinning electric potential of the memory region 135. Preferably, the pinning zone 121 and/or the pinning gate 114 are intended to deplete the memory region 135 in the absence of photogenerated electric charges.

Each controllable storage zone further comprises a transfer gate 111 and a reverse transfer gate 112. The transfer gate 111 extends vertically in the substrate 100 vertically in line with the photosensitive region 120 between the upper face 100.1 and the photosensitive region 120. It extends opposite the barrier 131. Preferably, as is the case here, it extends vertically opposite the memory region 135.

The reverse transfer gate 112 extends vertically in the substrate 100 opposite the barrier 131 and an upper part of the photosensitive region 120, preferably opposite the entire photosensitive region 120. Advantageously, the reverse transfer gate 112 extends substantially to the lower face of the substrate 100. It herein delimits a lateral face of the photosensitive region 120. It extends in a plane parallel to the plane (Y, Z). In a plane parallel to the upper face 100.1 and along a direction parallel to the axis X, the distance Px separating an outer edge of the reverse transfer gate 112 of the first controllable storage zone to an inner edge of the reverse transfer gate 112 of the second controllable storage zone defines a size of the depth pixel 5. In this example, the pixel size Px is equal to 1.2 μm. It can be less than or equal to 1.2 μm, or even less than or equal to 1 μm. The photosensitive region 120 extends in a direction parallel to X, from a reverse transfer gate 112 of a controllable storage zone to the reverse transfer gate 112 of the other controllable storage zone.

One or more horizontal distances separating the transfer gate 111 from the reverse transfer gate 112 at the barrier 131 and a dopant concentration of the barrier 131 are capable of creating an electric potential barrier at the barrier 131, between the photosensitive region 120 and the memory region 135. Similarly, one or more horizontal distances separating the transfer gate 111 from the pinning gate 114 and a dopant concentration of the memory region 135 are capable of creating an electric potential well at the memory region 135, between the barrier 131 and the pinning zone 121. The transfer gate 111 and the reverse transfer gate 112 are facing each other at the barrier 131 so that the latter can be controlled indifferently by either of the transfer gate 111 or the reverse transfer gate 112, or simultaneously by both.

In this example, the photosensitive region 120, the barrier 131 and the memory region 135 are doped with a first type of conductivity. Here, the first type of conductivity is of the n type. The barrier 131 and the memory region 135 have dopant concentrations equal to N1 and N2, respectively, such that N1 is strictly less than N2.

The barrier 131 extends horizontally from the transfer gate 111 to the reverse transfer gate 112. The memory region 135 extends horizontally from the transfer gate 111 to the pinning gate 114. Here, the pinning gate 114 occupies a notch made in the reverse transfer gate 112. It is substantially planar and parallel to the plane (Y, Z).

The additional flow path extends vertically in the substrate 100, between the respective transfer gates 111 of the first and second controllable storage zones, and vertically in line with the photosensitive region 120. The collection channel 133 is arranged between the photosensitive region 120 and the collection zone 125. The collection channel 133 constitutes an electric potential barrier for the electric charges intended to be photogenerated in the photosensitive region 120. The collection zone 125 constitutes an electric potential well for the photogenerated electric charges.

In this example, the collection channel 133 and the collection zone 125 are doped with the first type of conductivity. The collection channel 133 can have a dopant concentration equal to the barrier 131, as is the case in this example. If applicable, the doping of the collection channel 133 and of the barrier 131 can result from in-situ doping during epitaxial growth. The epitaxial growth can comprise forming the photosensitive region 120.

The collection channel 133 extends horizontally from the transfer gate 111 of the first controllable storage zone to the transfer gate 111 of the second controllable storage zone.

All the gates of the first controllable storage zone among a set of gates consisting of the transfer gate 111, the reverse transfer gate 112, and the pinning gate 114, can each be flush with the upper face 100.1 of the substrate 100, without this being essential. Each gate of the set of gates comprises an electrode 102 made of an electrically conductive material, such as a metal or a doped semiconductor. The electrodes 102 are advantageously made of the same material. Here, they are all made of doped polycrystalline silicon. They are doped with a second type of conductivity opposite to the first type of conductivity, that is to say p-doped in this example.

The photosensitive region 120 can be doped or intrinsic. A geometry of the reverse transfer gate 112 and a dopant concentration of the photosensitive region 120 are such that the memory region 135 of each controllable storage zone has an intermediate electric potential between an electric potential of the photosensitive region 120 and an electric potential of the collection zone 125, when all the gates of the set of gates are at the same electric potential. The electric potential of the photosensitive region 120 can be equal to the electric potential of the memory region 135.

The electrode 102 of each gate of the set of gates is coated with a dielectric coating 129 of the gate. The dielectric coatings 129 are made of any dielectric material. Herein they are of silicon oxide. Each gate is electrically insulated from the semiconductor substrate 100 by a dielectric coating 129. A dielectric coating 129 electrically insulates the electrode 102 of the pinning gate 114 from the electrode 102 of the reverse transfer gate 112.

The transfer gate 111 comprises an insulating region 139 covering the electrodes 102 and flush with the upper face 100.1 of the substrate 100. The insulating region 139 is made of any dielectric material. Herein it is of silicon oxide.

The pinning zone 121 is doped with the second type of conductivity, p-doped in this example. It advantageously comprises a peripheral doped zone 141 common to the first and second controllable storage zones, extending horizontally in a peripheral region of the depth pixel 5. The pinning zone 121 has a concentration P1 of dopant elements. It can extend deeper into the substrate 100 at its peripheral doped zone 141. In this example, it extends vertically in the substrate 100 over a substantially constant depth, for example greater than or equal to a height along the axis Z of the insulating regions 139. The pinning zones 121 with their common peripheral doped zone 141 can for example be obtained by a single localized implantation step. Here, the peripheral doped zone 141 surrounds the transfer gate 111 of each controllable storage zone. It extends horizontally over substantially the entire surface of the depth pixel 5, in a top view. It is in contact with the pinning gate 114 of each controllable storage zone. Here, it is in contact with the reverse transfer gate 112 of each controllable storage zone. The pinning zones 121 with their common peripheral doped zone 141 form a one-piece doped zone.

The transfer gate 111 of a controllable storage zone is arranged in the depth pixel 5 so as to screen in the corresponding barrier 131, an electric field emitted by the transfer gate 111 of the other controllable storage zone, when the image sensor is in operation. The respective transfer gates 111 of the first and second controllable storage zones are herein separated by a distance S measured parallel to the axis X.

For better control of the collection channel 133, the distance S is preferably chosen equal to a minimum distance allowed by design rules of the technology used to make the sensor. Design rules generally take into account a minimum distance allowed between an electric contact and a vertical gate, and a minimum dimension for an electric contact. By way of example, the distance S is between 10 nm and 300 nm, here equal to 108 nm.

The transfer gate 111 has the shape of a U in a top view, surrounding the flow path. It comprises a main portion forming the base of the U, extending parallel to the plane (Y, Z), as well a first branch and a second branch of the U extending parallel to the plane (X, Z). In this example, the main portion and the first branch have horizontal widths substantially equal to a value W. The second branch here has a horizontal width strictly greater than W. The horizontal width of the second branch is for example sufficient to ensure that a first contact 161 of the readout circuit rests entirely on the second branch despite manufacturing uncertainties.

W can be between 20 nm and 300 nm. W is here equal to 100 nm. The width of the second branch is here equal to 200 nm. The first and second branches have lengths equal to WN, measured parallel to the axis X. W_{N} is for example between 10% and 40% of the pixel size Px, here equal to 326 nm. The first branch is separated from the second branch by a distance L_{N} measured parallel to the axis Y, here equal to 640 nm. The transfer gate 111 can extend in the substrate 100 over a depth between 0.2 μm and 1.5 μm. The insulating region 139 may have a height measured parallel to the axis Z less than 600 nm, here equal to 100 nm.

The transfer gate 111 may have other shapes in a top view, such as for example the shape of an L or an I, with or without serifs.

In this example, the reverse transfer gate 112 has a substantially constant horizontal width, for example between 20 nm and 300 nm, here equal to 100 nm. The pinning gate 114 is aligned with the reverse transfer gate 112. Here, it has a horizontal width equal to that of the reverse transfer gate 112.

The collection zone 125 is n-type doped. It comprises, as represented in FIG. 1B, an N-doped region 143 and an optional N-cavity 142. The N-doped region 143 extends horizontally from the main portion of the transfer gate 111 of a controllable storage zone to the main portion of the transfer gate 111 of the other controllable storage zone. The collection zone 125 extends vertically in the substrate 100 from the upper face 100.1, over a depth greater than the height of the isolating regions 139. The N-doped region 143 may comprise an overdoped region flush with the upper face 100.1, formed inside the N-doped region 143, so as to reduce an electric contact resistivity between the collection zone 125 and the readout circuit.

The N-cavity 142 extends horizontally from the main portion of the transfer gate 111 of a controllable storage zone to the main portion of the transfer gate 111 of the other controllable storage zone. It extends vertically in the substrate 100 deeper than the N-doped region 143. Viewed from above, the N-doped region 143 occupies for example a pixel surface located within the N-cavity 142. Here, the N-cavity 142 extends along the axis Y, between the main portions of the respective transfer gates 111 of the first and second controllable storage zones, over a length strictly less than an opposite length, along which the transfer gates 111 are facing each other when viewed from above. Thus, the collection zone 125 extends along the axis Y over a length L_{C} strictly less than the opposite length. In FIG. 1A, it is centered on the center of the depth pixel 5.

A vertical doping profile of the collection zone 125 is chosen to increase a proportion of electric charges transferred by the collection channel 133 when the respective transfer gates 111 of the first and second controllable storage zones are activated simultaneously. By way of example, in this embodiment, the N-cavity 142 extends vertically in the substrate 100 deeper than the memory regions 135 to promote the transfer of electric charges from the photosensitive region 120 to the collection zone 125, during a reset phase of the photosensitive region 120 and/or between samplings of as sampling phase T1 and/or during sample read waiting phase, when the sensor is in operation.

The length Lc is for example greater than or equal to 100 nm. The length Ly can be between 15% and 60% of the pixel size Pₓ, here equal to 584 nm. The N-doped region 143 has a concentration of donor-type dopant elements of between 1E16 at/cm3 and 5E20 at/cm3. The N-cavity 142 has a concentration of donor-type dopant elements of between 1E16 at/cm3 and 1E19 at/cm3. Advantageously, the concentration of dopant elements of the N-doped region 143 is strictly higher than N2.

The memory region 135 extends deep from the pinning zone 121 to the barrier 131. The pinning gate 114 extends deep into the substrate 100 from the upper face 100.1. Preferably, it extends until it substantially reaches a separation plane between the memory region 135 and the barrier 131, within manufacturing tolerances.

The respective electrodes 102 of the pinning gate 114 and of the reverse transfer gate 112 are insulated from one other by the dielectric coating 129. They are for example separated by the dielectric coating 129 by a distance between 2 nm and 100 nm, here equal to 20 nm. Here, the dielectric coatings 129 of all the electrodes 102 of the set of gates have substantially equal thicknesses.

N1 is for example between 1E10 at/cm3 and 1E18 at/cm3. N2 is for example between 1E16 at/cm3 and 1E19 at/cm3. P1 is for example between 1E17 at/cm3 and 5E20 at/cm3.

The depth pixel 5 comprises two peripheral isolation trenches 115 delimiting the pixel. Each peripheral isolation trench 115 extends vertically in a peripheral region of the pixel, along a plane parallel to the plane (X, Z). It extends vertically in the substrate 100, facing the photosensitive region 120. In this example, it is flush with the upper face 100.1. Preferably, it extends vertically over a depth substantially equal to the thickness of the substrate 100.

In this example, the peripheral isolation trenches 115 extend along 2 opposite faces of the depth pixel 5. Each comprises a vertical electrode 106 coated with a dielectric coating 129. The dielectric coating 129 of the peripheral isolation trench 115 electrically insulates the vertical electrode 106 from the substrate 100. Here, each peripheral isolation trench 115 further comprises an insulating region 139 covering the vertical electrode 106 and flush with the upper face 100.1 of the substrate 100. The vertical electrode 106 is for example made of doped polycrystalline silicon. The dielectric coating 129 is for example made of silicon oxide. The insulating region 139 is for example of silicon oxide. Each vertical electrode 106 is electrically connected to the readout circuit.

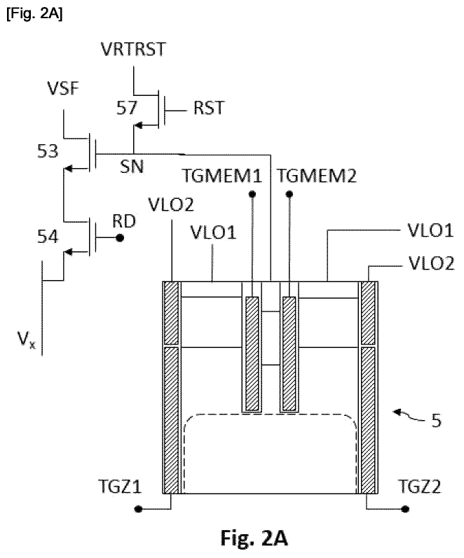

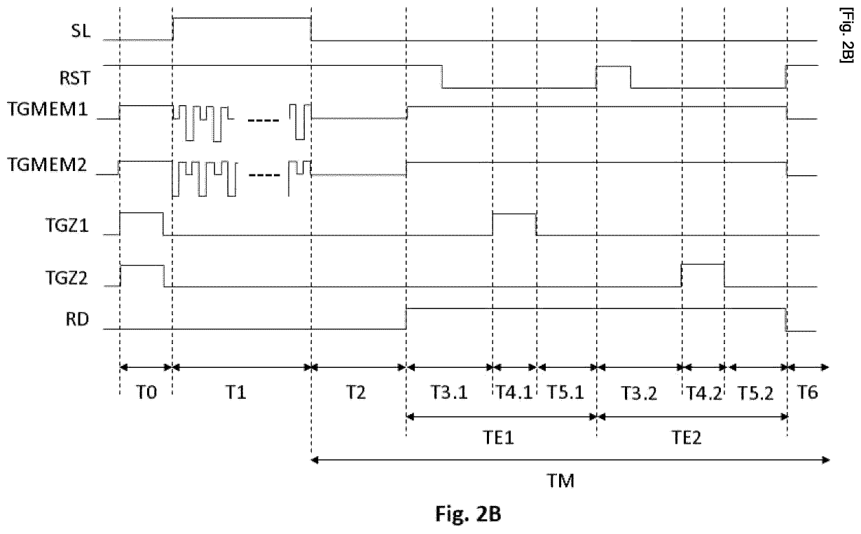

In relation to FIG. 2A, a readout circuit of the sensor, adapted to the example of a depth pixel 5 of FIGS. 1A and 1B, will now be described. FIG. 2A shows the cross-sectional view of FIG. 1B again without the references. Electric connections electrically connecting the various elements of the depth pixel 5 to the readout circuit are schematically shown, but are not necessarily representative of a geometric arrangement in space.

The readout circuit comprises a first contact 161, a second contact 162, a fourth contact 164, and a seventh contact 167, per controllable storage zone. The readout circuit further comprises a sixth contact 166, also called the reset electric contact 166.

The pinning gates 114 are each electrically connected via a respective fourth contact 164, to a node or a rail for supplying an electric potential VLO2. The reverse transfer gate 112 of the first (respectively second) controllable storage zone is electrically connected via the second contact 162, to a node or a rail for supplying an electric potential TGZ1 (respectively TGZ2). The transfer gate 111 of the first (respectively second) controllable storage zone is electrically connected via the first contact 161, to a node or a rail for supplying an electric potential TGMEM1 (respectively TGMEM2).

Each pinning zone 121 is electrically connected to a node or rail for supplying an electric potential VLO1, via the seventh contact 167. Alternatively, the readout circuit may have only a seventh contact 167 per depth pixel 5, and the pinning zone 121 devoid of electric contact is electrically connected to the other pinning zone 121 via the peripheral doped zone 141.

Each read block further comprises a transistor 53 mounted in a source follower and a selection transistor 54. The transistors 53 and 54 are NMOS transistors here. The drain of the transistor 53 is electrically connected to a node or a rail for supplying an electric potential VSF. The source of the transistor 53 is electrically connected to the drain of the selection transistor 54. The source of the selection transistor 54 is electrically connected to an output line having an electric potential Vx. The output line is connected to a column footer of the array of pixels. The gate of the selection transistor 54 is electrically connected to a node or a rail for supplying an electric potential RD. The collection zone 125 is electrically connected to a sense node SN of the readout circuit, via the sixth contact 166. The sense node SN is electrically connected to the gate of the transistor 53. It is further electrically connected to a node or a rail for supplying an electric potential VRTRST via the channel of a reset transistor 57 of the readout circuit. The reset transistor 57 is controlled by an electric potential RST. This is an NMOS transistor here.

FIG. 2B illustrates a possible operation of this readout circuit. It represents a timing diagram on which electric potentials varying over time have been reported. Some of these are marked with solid discs on the electrical diagram of FIG. 2A.

When a scene is illuminated by a light source having a periodic amplitude having the period P_{S}, the timing diagram leads to an integration in each controllable storage zone, of part of the light signal reflected by the scene, over periodic time intervals having a period equal to the period P_{S} and duration equal to P_{S}/4.

The timing diagram is adapted to an image sensor comprising several depth pixels 5 arranged in an array. It successively comprises a reset phase T0, a sampling phase T1 and a phase of reading the array TM. The reading phase of the array TM consists of, successively, a first optional waiting phase T2, a phase of reading a first sample TE1, a phase of reading a second sample TE2, and a second optional waiting phase T6. The combination of the consecutive phases T0, T1 and TM constitutes a phase of acquiring a depth image, or acquiring a frame, for example if the sensor is capable of capturing several successive images. Where applicable, the phase of reading the array TM of a frame can be immediately followed by the phase T0 of resetting the next frame.

In order to determine a piece of depth information from the periodic light signal received by the sensor during a phase of acquiring an image, the depth pixel 5 can belong to a macro-pixel Z comprising several identical depth pixels 5. Where applicable, the phases T1 of sampling depth pixels 5 distinct from the macro-pixel Z are offset by a fraction of the period P_{S}, modulo the period P_{S}. A macro-pixel Z may for example consist of 2 depth pixels 5 having their sampling phases T1 offset by a quarter of the period P_{S}, modulo the period Ps.

Alternatively, information on depth can be determined from the periodic light signal received by the sensor during phases of acquiring successive frames. By way of example, the phases T1 of sampling two successive frames may be offset by a quarter of the period P_{S} modulo the period P_{S}, or the light signal is offset by a quarter of the period P_{S} modulo the period P_{S} from one frame to the next. Information on depth is then determined from the samples collected by the depth pixel 5 during the phases of acquiring the two successive frames. Other arrangements are further possible, allowing to acquire information on depth from samples collected over several frames with a macro-pixel Z of at least one depth pixel 5.

By way of example, it is possible to calculate a phase shift between Δφ the light signals emitted and received allowing determining a distance from the sensor to the scene from four samples C0, C1, C2 and C3, by applying the formula

$$Δφ = arctan ( \frac{C 3 - C 1}{C 0 - C 2} ) .$$

C0 C1, C2, C3 correspond to quantities of photo-generated charges during time intervals equal to P_{S}/4, immediately succeeding each other in this order, without overlapping each other.

The reading phase of a first (respectively second) sample TE1 (respectively TE2) consists of, successively, a phase T3.1 (respectively T3.2) of reading an electric potential Vinit1 (respectively Vinit2), a first (respectively second) charge evacuation phase T4.1 (respectively T4.2), and a phase T5.1 (respectively T5.2) of reading an electric potential Vsig1 (respectively Vsig2).

During the phase of acquiring an image or a frame, the electric potentials VLO1, VLO2, VSF and VRTRST are fixed. By way of example, VLO1 is equal to −0.5 V or 0 V. VLO2 is for example equal to −0.8 V. VSF is for example equal to 1.8 V, 2.5 V or 3.3 V. VRTRST is for example equal to 1.8 V, 2.5 V or 3.3 V.

VL02 is strictly lower than VL01 so that, in each controllable storage zone, holes coming from the pinning zone 121 are attracted along the pinning gate 114 by an electric field between the pinning zone 121 and the pinning gate 114 and thus form an inversion region in contact with the pinning gate 114. The inversion region forms with the memory region 135 a lateral junction passivating the memory region 135.

Similarly, an electric contact not represented in FIG. 1A, connects each vertical electrode 106 to a fixed electric potential for passivating regions of the depth pixels 5 facing the peripheral isolation trenches 115.

The reset transistor 57 is kept on (RST at a high value) during the reset and sampling phases T0, T1, as well as during the first and second waiting phases T2, T6.

During the reset phase T0, the photosensitive region 120 and the memory region 135 are emptied of possible electric charges that they could contain. For this, the electric potentials TGMEM1, TGMEM2, TGZ1 and TGZ2 are initially all four equal to a high value V_{H}. The depth pixel 5 is in a bias state for which, from each controllable storage zone, the electric potential increases along an oriented path successively connecting the memory region 135, the barrier 131, the photosensitive region 120, the collection channel 133 and the collection zone 125. Electrons contained in the memory region 135 of each controllable storage zone thus flow, under the action of an electric field along the path, from the memory region 135 to the collection zone 125.

Once the memory region 135 is empty of electric charges, i.e. reset, TGZ1 and TGZ2 are switched to a low value V_{L}, while TGMEM1 and TGMEM2 are maintained at the high value V_{H}. The low value V_{L} is in this example equal to −0.8 V. The value V_{H} is equal to 2.5 V. The difference in electric potential between the photosensitive region 120 and the memory region 135 of each controllable storage zone changes sign. The transfer of electric charges from the photosensitive region 120 to the collection zone 125 is preferential. It is maintained preferential for an adjustable time allowing the start of the sampling phase T1, for example, to be set relative to the sampling phase T1 of another cooperating depth pixel 5 to obtain information on depth. Thus, the photosensitive region 120 is devoid of electric charges at the beginning of the sampling phase T1, i.e. it is reset.

A configuration of the depth pixel 5, including the distance S and a doping profile of the additional flow path, is such that the high value V_{H} is sufficient to create an electric field making the electric charges of the photosensitive region 120 converge preferentially towards the collection channel 133. Thus, any electrons present in the photosensitive region 120, some of which may come from the memory region 135, transit from the photosensitive region 120 to the collection zone 125. The electric potential gradient is maximum in absolute value in the direction of the collection zone 125. In this configuration, the electric potential decreases on either side of the center of the depth pixel 5, along an axis parallel to X at the lower faces of the transfer gates 111. Therefore, an electric potential difference σV exists along this axis, between a face of each transfer gate 111 facing the corresponding memory region 135 and an opposite face of the same transfer gate 111 facing the collection channel 133. For example, an electric potential difference σV greater than or equal to 110 mV in absolute value is sufficient for at least 97% of the charges transferred from the photosensitive region 120 to reach the collection zone 125. The proportion of charges transferred and σV increase as V_{H} increases and/or S decreases and/or the depth of the collection zone 125 increases.

During the sampling phase T1, a periodic pulse train is applied to the transfer gate 111 of each controllable storage zone. TGMEM1 and TGMEM2 are each a periodic square wave having the period P_{S}, taking the values V_{L}, V_{H} and Vᵢ. Vᵢ is strictly greater than V_{L} and less than or equal to VA. Here, each square has a duration equal to P_{S}/4. At each period of the square wave, TGMEM1 switches successively from Vᵢ, to V_{H}, then to V_{L} and finally to V_{H}. TGMEM2 switches simultaneously and in opposite phase to TGMEM1. TGZ1 and TGZ2 are maintained at the low value V_{L} during the entire sampling phase T1. The electric potential of the photosensitive region 120 is therefore strictly lower than the electric potential of the memory region 135 of each controllable storage zone.

The value Vᵢ is sufficient to lower the potential barrier between the photosensitive region 120 and the memory region 135, thus allowing photo-generated charges to be collected in the memory region 135. Furthermore, the configuration of the depth pixel 5, including the distance S and a doping profile of the additional flow path, makes the transfer of electric charges from the photosensitive region 120 to the collection zone 125 preferential when the transfer gates 111 of the first and second controllable storage zones are both biased to an electric potential greater than or equal to Vᵢ.

During the sampling phase T1, the photogenerated charges are transferred in the photosensitive region 120, successively to the memory region 135 of the first controllable storage zone (TGMEM1 to Vᵢ, TGMEM2 to V_{L}), the collection zone 125 (TGMEM1 to V_{H}, TGMEM2 to V_{H}), the memory region 135 of the second controllable storage zone (TGMEM1 to V_{L}, TGMEM2 to Vᵢ), and finally to the collection zone 125 (TGMEM1 at V_{H}, TGMEM2 at V_{H}). At the end of the sampling phase T1, the memory region 135 of each controllable storage zone contains a quantity of photo-generated electric charges corresponding to a sample.

Throughout the sampling phase T1, the light signal is active (reference SL in the timing diagram). Preferably, the light signal SL is only active at the time of the sampling phase T1. Means, such as a clock or a synchronization signal, allow to synchronize the light signal with the readout circuit. These means can be external or integrated into the sensor, in whole or in part. Alternatively, the sensor can comprise means for blocking the light signal reflected by the scene before reaching the photosensitive region 120, outside of the sampling phase T1.

The first waiting phase T2 follows the sampling phase T1. This is a waiting phase for selection of the row or column of the array to which the depth pixel 5 belongs. This phase is generally used to read other rows or columns. During this phase TGZ1 and TGZ2 are equal to V_{L}, while TGMEM1 and TGMEM2 are equal to Vᵢ. This situation allows a preferential transfer of the electric charges from the photosensitive region 120 to the collection zone 125. It makes it possible to prevent any additional electric charges generated in the photosensitive region 120 after the sampling phase T1 from being transferred to a memory region 135 between the sampling phase T1 and reading the value of the sample collected in the memory region 135 during the sampling phase T1. This function is sometimes called anti-blooming.

The first waiting phase T2 is followed by the phase of reading a first sample TE1 collected by the first controllable storage zone. It starts with an optional phase of reading T3.1 an electric potential Vinit1. The reading phase T3.1 begins when the selection transistor 54 is switched to an on state (RD to a high value). TGMEM1 and TGMEM2 can be maintained at Vᵢ. Preferably, TGMEM1 and TGMEM2 are kept equal to a same electric potential greater than or equal to Vᵢ, constant during the phases of reading the first and second samples TE1, TE2. Here, TGMEM1 and TGMEM2 are switched to V_{H}, simultaneously with switching the selection transistor 54 to the on state.

The reset transistor 57 is maintained on (RST at a high value) before being switched to an off state (RST at a low value), for a duration allowing a first reset of the sense node SN. At the time when RST is switched, the light signal is already interrupted or blocked so that no electric charge is photogenerated by the light signal. The sense node SN is thus reset at an electric potential Vinit1, substantially constant until the end of the reading phase T3.1, corresponding to VRTRST plus an electric potential V_{kTC} corresponding to a thermal noise of the readout circuit. The value of the electric potential Vinit1 is read on the output line and stored at the column footer. The sense node SN has a capacitance C_{SN}. The capacitance C_{SN} is not necessarily an independent component of the readout circuit. It can be induced by various factors related to the design and the materials, for example such as interconnection lines, one or more transistor gates, etc.

A first charge evacuation phase T4.1 follows the reading phase T3.1. It starts when TGZ1 switches to the high value V_{H}. TGZ2, TGMEM1 and TGMEM2 are respectively maintained at V_{L}, V_{H} and V_{H} during the entire first charge evacuation phase T4.1. The depth pixel 5 is in a bias state for which the electric potential increases along a first passageway, from the memory region 135 of the first controllable storage zone to the collection zone 125, passing through the photosensitive region 120. Electrons contained in the memory region 135 of the first controllable storage zone thus flow under the effect of an electric field, from the memory region 135 to the collection zone 125. Alternatively, the flow of electrons under the effect of the electric field, from the memory region 135 to the collection zone 125, takes place in two steps: a first step during which electrons flow to the photosensitive region 120 when TGZ1 is at the high value V_{H}, and a second step during which electrons flow from the photosensitive region 120 to the collection zone 125 when TGZ1 switches to the low value V_{L}.

At the end of the first charge evacuation phase T4.1, the memory region 135 of the first controllable storage zone is emptied of electric charges that had been transferred from the photosensitive region 120 during the sampling phase T1. It returns to its pinning potential. The photo-generated charges reach the collection zone 125 and charge the capacitance C_{SN} of the sense node SN to an electric potential Vsig1.

The first charge evacuation phase T4.1 is followed by a phase of reading T5.1 the electric potential Vsig1. The reading phase T5.1 starts after switching TGZ1 to the low value V_{L}, TGMEM1 and TGMEM2 being maintained at V_{H}. The value of the electric potential Vsig1 is read on the output line and stored at the column footer. Vsig1 is representative of the number of electric charges photogenerated and collected in the memory region 135 during the sampling phase T1.

The reading phase T5.1 is followed by the phase of reading a second sample TE2 collected by the second controllable storage zone. It starts with an optional phase of reading T3.2 an electric potential Vinit2. The reading phase T3.2 begins when the reset transistor 57 switches to an on state (RST at a high value). TGMEM1, TGMEM2, TGZ1 and TGZ2 are maintained at their respective electric potentials. The reading phase T3.2 is similar to the reading phase T3.1. The reset transistor 57 is maintained on before being switched to an off state (RST at a low value), for a period allowing a second reset of the sense node SN. The sense node SN is reset to an electric potential Vinit2 corresponding to VRTRST plus an electric potential corresponding to the state of the noise kTC on the sense node SN at the time of closing the channel of the reset transistor 57.

The reading phase T3.2 is followed by a second charge evacuation phase T4.2. The sequence of the timing diagram during the second charge evacuation phase T4.2 is similar or identical to that of the first charge evacuation phase T4.1, by reversing TGZ2 and TGZ1. Electrons contained in the memory region 135 of the second controllable storage zone flow under the effect of an electric field, from the memory region 135 to the collection zone 125. The memory region 135 returns to its pinning potential. The photo-generated charges stored in the second controllable storage zone reach the collection zone 125 and charge the capacitance C_{SN} of the sense node SN to an electric potential Vsig2.

The second charge evacuation phase T4.2 is followed by the phase of reading T5.2 the electric potential Vsig2. The sequence of the timing diagram during the reading phase T5.2 is similar or identical to that of the reading phase T5.1. The reading phase T5.2 ends when the selection transistor 54 is switched to an off state (RD at a low value). The value of the electric potential Vsig2 is read on the output line and stored at the column footer. Vsig2 is representative of the number of electric charges photogenerated and collected in the memory region 135 of the second controllable storage zone during the sampling phase T1.

In this example, the sensor comprises means for carrying out a correlated double sampling. The means especially comprise the reading phases T3.1 and T3.2, storage of the electric potentials Vinit1 and Vinit2 read at the column footer and an analog cell producing signals proportional respectively to the difference of Vinit1 and Vsig1, and to the difference of Vinit2 and Vsig2. For example, the analog cell subtracts Vsig1 from Vinit1 to obtain the value of the first sample, and Vsig2 from Vinit2 to obtain the value of the second sample. Since the readings of Vinit1 and Vsig1 are consecutive, without modification of the state of the reset transistor 57 between the reading phases T3.1 and T5.1, reading Vsig1 does not suffer any additional thermal noise to that already present when reading Vinit1. Thus, subtracting Vinit1 from Vsig1 allows to suppress the kTC noise. The readings of Vsig1 and Vinit1 are said to be correlated. Similarly, the readings of Vinit2 and Vsig2 are consecutive, without modification of the state of the reset transistor 57. The readings of Vsig2 and Vinit2 are correlated.

The phase of reading the second sample TE2 is followed by an optional second waiting phase T6 during which other rows of the array of pixels are optionally selected. The electric potentials of the timing diagram are at values identical to those of the first waiting phase T2. After the second waiting phase T6, for example immediately after, the phases of reset T0, sampling T1 and reading the array TM can be repeated to acquire another frame.

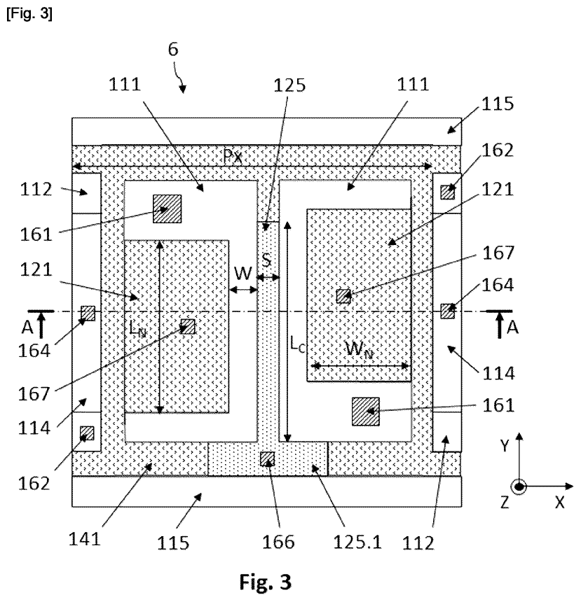

In FIG. 3, a top view of a depth pixel 6 has been represented, making it possible to decrease the distance S. This is an alternative to the depth pixel 5 of FIG. 1A for which FIG. 1B is also a cross-sectional view along the sectional plane A-An of FIG. 3. Only the differences with this alternative are explicitly described.

In FIG. 3, the pixel further comprises a peripheral contact zone 125.1 on which the reset electric contact 166 rests. The peripheral contact zone 125.1 is in physical and electric contact with the collection zone 125. For example, it is formed as one piece with the collection zone 125. It is doped with the same type of conductivity as the collection zone 125, here n-type. It extends deep in the substrate 100 from the upper face 100.1. In this example, it extends horizontally from the collection zone 125 and from the transfer gates 111, until reaching the peripheral isolation trench 115. For example, it has a height along the axis Z, less than or equal to the height of the collection zone 125, without this being essential.

The peripheral contact zone 125.1 has dimensions and a dopant concentration that are adjusted so as not to create a potential barrier or well between the collection zone 125 and the reset electric contact 166 when the sensor is in operation. When the peripheral contact zone 125.1 and the collection zone 125 are of equal heights, they can be made with the same series of method steps. They then have substantially identical doping profiles along the axis Z, as is the case here.

Viewed from above, the reset electric contact 166 is offset in a peripheral region of the depth pixel 6 making it possible to move the transfer gates 111 closer to each other, without breaking a design rule of the technology used to make the sensor, such as a minimum spacing rule between a contact and a vertical gate. The distance S can thus be reduced relative to the depth pixel 5 of FIG. 1A. It is here equal to 70 nm. The transfer gates 111 moving closer to each other makes it possible to increase storage capacity of the memory regions 135 and/or to promote transfer of the photo-generated charges from the photosensitive region 120 to the memory regions 135 during the sampling phase T1.

In this alternative, the contour of the peripheral doped zone 141 conforms to the peripheral isolation trench 115 when viewed from above, except for a region of the pixel inside which the peripheral contact zone 125.1 is in contact with the peripheral isolation trench 115.

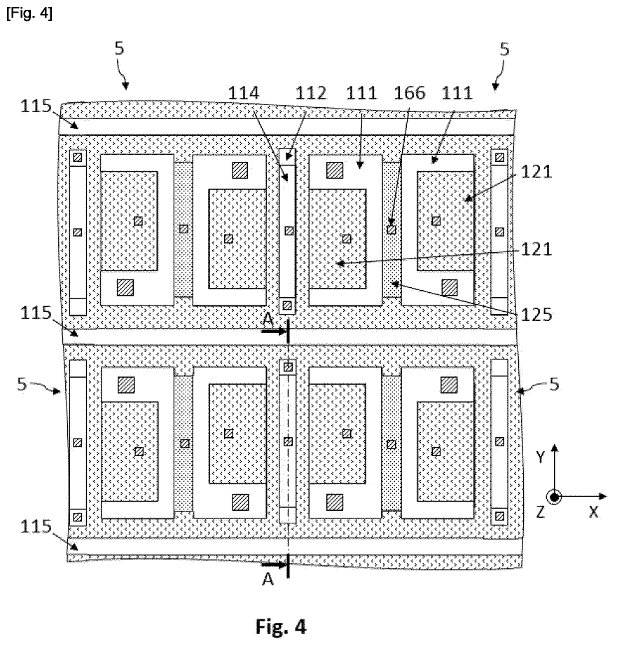

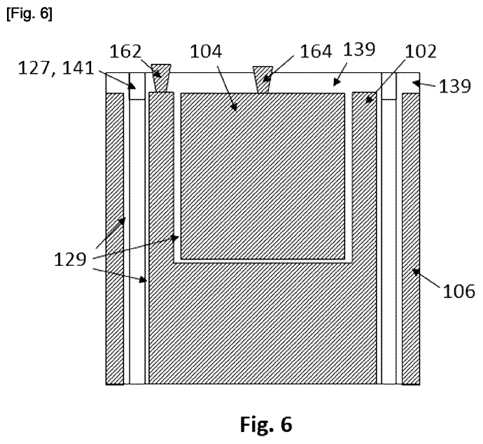

A sensor comprising an array of depth pixels 5 will now be described in relation with FIG. 4. All the depth pixels 5 are identical. Each depth pixel 5 is similar or identical to that of FIGS. 1A and 1B. FIG. 6 is a schematic view along the cross-section A-A of FIG. 4.

In FIG. 4, a subarray of the array consisting of two rows and two columns has been represented. The rows of depth pixel 5 extend along the axis X, the columns along the axis Y. The reverse transfer gates 112 of two contiguous controllable storage zones belonging to two depth pixels 5 of a same row are actuated simultaneously. The adjustable delays of the reset phases T0 of two depth pixels 5 may be different if the latter cooperate to obtain a piece of depth information. For example, it is possible to cooperate two depth pixels 5 of a same row or of a same column, to obtain a piece of distance information. A timing diagram similar to that of FIG. 2B may be applied to each depth pixel 5. The depth pixels 5 can be read row by row or column by column.

Each reverse transfer gate 112 and each pinning gate 114 are common to two contiguous depth pixels 5 of the array. The latter are for example symmetrical to each other with respect to the vertical plane in which the reverse transfer gate 112 and the pinning gate 114 extend, as is represented here.

Each peripheral isolation trench 115 is common to two contiguous depth pixels 5. Thus, the peripheral isolation trenches 115 of the array form, in a top view, a set of one-piece rows separating two rows of depth pixels 5 of the array. The vertical electrodes 106 form one-piece vertical walls separating two contiguous rows of depth pixels 5. Each row of vertical electrodes 106 is here connected to the fixed potential by an electric contact arranged at the periphery of the array.

The peripheral doped zones 141 of two contiguous depth pixels 5 of a same row meet at the plane of the common reverse transfer gate 112, to form a one-piece zone. Each depth pixel 5 may be a depth pixel 6 according to FIG. 3, having a peripheral contact zone 125.1 extending from the collection zone 125 in a peripheral region of the pixel on which the reset electric contact 166 rests.

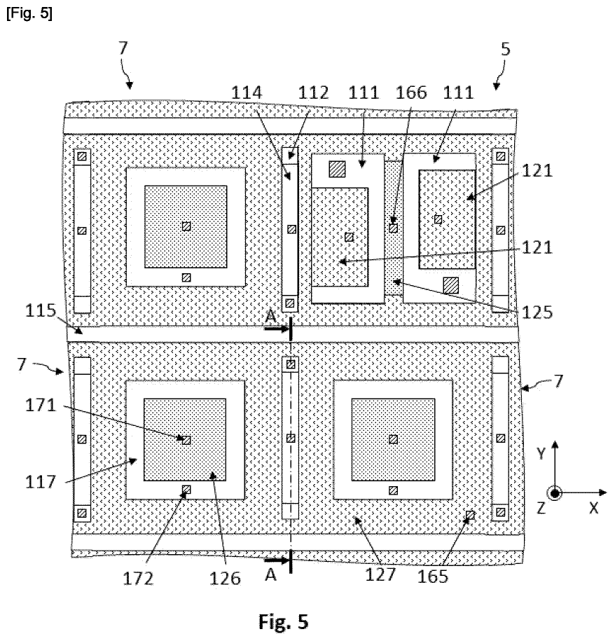

A sensor comprising an array of pixels mixing intensity pixels 7 and depth pixels 5 will now be described. Several intensity pixels 7 can be inserted into the array of pixels. FIG. 5 shows a set of 4 pixels of the array in a top view. FIG. 6 is also a view along the cross-section A-A of FIG. 5. The set of 4 pixels is for example repeated periodically to form the array. Here, it comprises 3 intensity pixels 7 and one depth pixel 5. Only the differences with the sensor of FIG. 4 are explicitly described. The depth and intensity pixels 5, 7 have superimposable horizontal footprints, that is to say that all their horizontal dimensions are equal.

The depth pixel 5 is identical to that described in relation to FIG. 4. Each intensity pixel 7 can be any type of pixel delivering a signal proportional to the intensity of a part of the electromagnetic radiation coming from the scene and incident on the lower face of the substrate 100, not comprising the light signal. The intensity pixel 7 can for example be a pixel similar to or identical to that described in document US 2019/0237499 A1.

Each intensity pixel 7 comprises a transfer gate 117, a detection zone 126 and a cavity 127. It further comprises peripheral isolation trenches 115 identical to the depth pixel 5. The array of pixels of FIG. 5 is obtained by replacing depth pixels 5 of the array of FIG. 4 with intensity pixels 7. Thus, the peripheral isolation trenches 115 form, in a top view, a set of one-piece rows separating two rows of pixels of the array.

The detection zone 126 and the cavity 127 are doped with opposite types of conductivity. In this example, without this being essential, the cavity 127 is doped with the same type of conductivity as the pinning zone 121 and its peripheral doped zone 141. The cavity 127 and the pinning zone 121 can for example result from one or more shared implantation steps.

In FIG. 5, a first row of the array delimited by the peripheral isolation trenches 115 comprises two intensity pixels 7. A second row comprises a depth pixel 5 and an intensity pixel 7. In the first row, the cavities 127 meet to form a one-piece doped zone. Similarly, in the second row, the pinning zone 121 meets the cavity 127 to form another one-piece doped zone.

The transfer gate 117 extends vertically in the substrate 100 from the upper face 100.1. It has a substantially square or rectangular shape when viewed from above. It surrounds the detection zone 126 on all sides. The detection zone 126 extends from one edge to the other of the transfer gate 117. The cavity 127 extends from one peripheral isolation trench 115 to another. It surrounds the transfer gate 117.

Electric charges photogenerated in a photosensitive region of the intensity pixel 7 are collected in the detection zone 126 when the transfer gate 117 is activated. The transfer gate 117 is located vertically in line with this photosensitive region.

The depth pixel 5 does not share its reverse transfer gates 112 and its pinning gates 114 with a neighboring depth pixel 5. Advantageously, each intensity pixel 7 is separated from a neighboring pixel by a reverse transfer gate 112 and a pinning gate 114 identical to those of the depth pixel 5, and arranged in the same way. Thus, all the intensity pixels 7 have identical operating characteristics. The reverse transfer and pinning gates 112, 114 of the first row are advantageously biased by electric contacts, when the sensor is in operation.

For each intensity pixel 7, the detection zone 126 and the transfer gate 117 are connected to a control circuit by, respectively, a readout contact 171 and a gate contact 172 of the control circuit. The control circuit can be a part of the readout circuit or an independent circuit. The cavities 127 of the intensity pixels 7 of the first row are connected to the control circuit by a fifth contact 165. In operation, the cavity 127 of the intensity pixel 7 of the second row is here biased via the seventh contact 167 and the pinning zone 121 of the depth pixel 5.

By way of example, the sensor can be configured to capture a color image. The intensity pixels 7 of the set of 4 pixels can then each be sensitive in a range of wavelengths of the visible spectrum distinct from the other two intensity pixels 7 of the set. It is possible to associate them with a pixelized filter disposed facing the lower face of the substrate 100 so that each pixel is exclusively sensitive to one of the three colors of red, green or blue.

Particular embodiments have just been described. Different alternatives and modifications will appear to a person skilled in the art. The specific arrangement of the transfer and reverse transfer gates, between them and with respect to the flow path, is especially an element essential to the bidirectional transfer between the photosensitive region and the memory region allowing to achieve the compactness goal of the invention. This is usable in similar depth pixels, connected to other readout circuits, for example a readout circuit performing reading of the electric potentials Vsig1 or Vsig2 on a sense node coupled to the corresponding memory region by a capacitive coupling involving the transfer gate or the pinning gate.

Finally, it is within the scope of the person skilled in the art to make a depth pixel comprising more than two controllable storage zones from the technical teaching delivered above. For example, a depth pixel may comprise 4 controllable storage zones disposed at the four corners of the pixel. The transfer gates 111 can then have L-shapes in a top view, the faces of which are aligned on planes parallel to the plane (X, Z) or (Y, Z). The additional flow path extends vertically in line with the photosensitive region, opposite the four transfer gates, in a central region of the pixel. For example, it may have an orthogonal cross shape in a top view, extending horizontally from one transfer gate to another. The reverse transfer gate of each controllable storage zone may also have an L-shape, extending vertically opposite the corresponding flow path and delimiting an angle of the pixel.

1. An image sensor comprising a readout circuit and a plurality of pixels formed in and/or on a substrate of the sensor, such that at least one of the pixels is a depth pixel, each depth pixel comprising:
a photosensitive region of the substrate,
a first and a second controllable storage zones, each controllable storage zone comprising:
an electric charge flow path extending vertically in the substrate vertically in line with the photosensitive region and comprising a memory region which is a potential well and a barrier which is an electric potential barrier interposed between the memory region and the photosensitive region,
a transfer gate extending vertically in the substrate vertically in line with the photosensitive region, facing the barrier,
a reverse transfer gate extending vertically in the substrate facing the barrier and facing an upper part of the photosensitive region,
an additional electric charge flow path extending vertically in the substrate between the respective transfer gates (111) of the first and second controllable storage zones, vertically in line with the photosensitive region, comprising a collection zone which is an electric potential well and a collection channel which is an electric potential barrier interposed between the collection zone and the photosensitive region,
wherein the readout circuit comprises a sense node electrically connected to the collection zone and is configured to successively:
applying, in each controllable storage zone, a periodic pulse train to the transfer gate during a sampling phase common to the first and second controllable storage zones, so as to make electric charges flow from the photosensitive region to the memory region during the pulses, wherein the respective pulse trains of the first and second controllable storage zones are phase shifted relative to one another, and have the same period,
performing a first reset of the sense node,
performing a first charge evacuation during which the transfer gates of the first and second controllable storage zones, and the reverse transfer gate of the first controllable storage zone are activated so as to make the electric charges flow from the memory region of the first controllable storage zone to the collection zone,
reading an electric potential Vsig1 of the sense node,
performing a second reset of the sense node,
performing a second charge evacuation during which the transfer gates of the first and second controllable storage zones, and the reverse transfer gate of the second controllable storage zone are activated so as to make the electric charges flow from the memory region of the second controllable storage zone to the collection zone,
reading an electric potential Vsig2 of the sense node.

2. The image sensor according to claim 1, wherein the readout circuit is configured to read an electric potential Vinit1 of the sense node between the first reset and the first evacuation, and an electric potential Vinit2 of the sense node between the second reset and the second evacuation; wherein the image sensor is configured to perform a first correlated double sampling from Vinit1 and Vsig1, and a second correlated double sampling from Vinit2 and Vsig2.

3. The image sensor according to claim 1, wherein each controllable storage zone comprises a pinning gate; wherein, in each controllable storage zone, the flow path comprises a pinning zone covering the memory region on one side of the memory region opposite to the barrier, the pinning gate extends vertically in the substrate facing the memory region, and the readout circuit is configured to apply an electric potential difference between the pinning zone and the pinning gate so as to passivate the memory region from electric charges coming from the pinning zone.

4. The image sensor according to claim 3, wherein, in each controllable storage zone, the pinning gate is housed in a notch made in the reverse transfer gate.

5. The image sensor according to claim 1, wherein the collection zone extends vertically in the substrate, deeper than the memory regions of the first and second controllable storage zones.

6. The image sensor according to claim 1, wherein, for each depth pixel, the collection channel, the collection zone, the barrier and the memory region of each controllable storage zone are doped with a first type of conductivity, and each memory region has a dopant concentration strictly lower than a dopant concentration of the collection zone.

7. The image sensor according to claim 3, wherein, for each depth pixel (5, 6), the collection channel, the collection zone, the barrier and the memory region of each controllable storage zone are doped with a first type of conductivity, each memory region has a dopant concentration strictly lower than a dopant concentration of the collection zone, and wherein each pinning zone is doped with a second type of conductivity opposite to the first type of conductivity.

8. The image sensor according to claim 6, wherein the collection channel and the barrier of each controllable storage zone have identical dopant concentrations.

9. The image sensor according to claim 6, wherein, for each depth pixel, the transfer gate of each controllable storage zone has the shape of a U in a top view, surrounding the flow path.

10. The image sensor according to claim 6, wherein the readout circuit comprises one reset electric contact per depth pixel, and wherein each depth pixel comprises a peripheral contact zone of the first type of conductivity as one piece with the collection zone, arranged at the periphery of the depth pixel, on which the reset electric contact rests.

11. The image sensor according to claim 3, wherein, for each depth pixel and each controllable storage zone, the pinning gate occupies a notch made in the reverse transfer gate.

12. The image sensor according to claim 3, wherein the plurality of pixels is arranged in an array and wherein the pinning gates and the reverse transfer gates are arranged in separation planes between two pixels of the array of pixels.

13. The image sensor according to claim 12, wherein all the pixels of the array have the same size, and wherein the array of pixels comprises intensity pixels configured to deliver a signal representative of an intensity of an incident light radiation.
